(19) United States
(12) Patent Application Publication
(10) Pub. No.: US 2008/0101039 A1
(43) Pub. Date: May 1, 2008

(54) PASSIVE HEAT-DISSIPATING TYPE POWER SUPPLY APPARATUS FOR INCREASING HEAT-DISSIPATING EFFICIENCY AND FABRICATING PROCESS THEREOF

(75) Inventors: Jui-Yuan Hsu, Taoyuan (TW); Chien-Chung Chang, Taoyuan (TW); Wen-Ching Wu, Taoyuan (TW)

Correspondence Address: MADSON & AUSTIN, 15 WEST SOUTH TEMPLE, SUITE 900, SALT LAKE CITY, UT, 84101, US

(73) Assignee: Delta Electronics, Inc., Taoyuan (TW)

(21) Appl. No.: 11/764,856

(22) Filed: Jun. 19, 2007

(30) Foreign Application Priority Data
Oct. 31, 2006 (TW) 095140295

(51) Int. Cl. H05K 7/20; H01S 4/00

(52) U.S. Cl. 361/720; 29/592.1

(57) ABSTRACT

The present invention relates to a power supply apparatus having a passive heat-dissipating mechanism. The power supply apparatus includes an insulating housing, a printed circuit board and at least an electronic component. The insulating housing has a closed receptacle therein and includes a first edge, a second edge and a third edge. The first edge is greater than the second edge and the second edge is greater than or equal to the third edge. An aspect ratio of the first edge to the second edge is greater than 2.5. The electronic component is mounted on the printed circuit board.

### FIELD OF THE INVENTION

The present invention relates to a power supply apparatus, and more particularly to a power supply apparatus having a passive heat-dissipating mechanism for increasing heat-dissipating efficiency. The present invention also relates to a process for fabricating such a power supply apparatus.

### BACKGROUND OF THE INVENTION

Many electronic products such as notebook computers, personal digital assistant (PDAs), mobile phones and game consoles become essential information, communication or amusement in our daily lives. Usually, the user may simply plug a connector of a power supply apparatus into an AC wall outlet commonly found in most homes or offices so as to receive an AC voltage. The power supply apparatus will convert the AC voltage into a regulated DC output voltage for powering the electronic device and/or charging a battery built-in the electronic device.

Take a power adapter for example. The power adapter is electrically interconnected between an electronic product and an external power source. The AC voltage transmitted from the external power source is converted by the circuitry of a printed circuit board inside the power adapter into a regulated DC output voltage for powering the electronic device and/or charging a battery built-in the electronic device.

Referring to FIG. 1, a schematic perspective view of a conventional power adapter is illustrated. The power adapter comprises an insulating housing 11, a printed circuit board 12, a power input member 13 and a power output member 14. The insulating housing 11 is composed of an upper cover 111 and a lower cover 112. A receptacle 113 is defined between the upper cover 111 and the lower cover 112 for accommodating the printed circuit board 12 therein. The insulating housing 11 is substantially a rectangular housing, and includes a first surface 11a, a second surface 11b, a third surface 11c, a fourth surface 11d, a fifth surface lie and a sixth surface 11f. There are several electronic components mounted on the printed circuit board 12 to provide power conversion. For clarification, only two electronic components 15 and 16 are shown in this drawing. The power input member 13 and the power output member 14 are disposed on opposite sides of the insulating housing 11, and are electrically connected to the printed circuit board 12 (not shown). Via the power input member 13 and the power output member 14, the external power source and the electronic product are respectively connected to the power adapter 10. An AC voltage transmitted from the external power source is converted by the circuitry of a printed circuit board 12 inside the power adapter 10 into a regulated DC output voltage for powering the electronic product. During power conversion, the electronic components 15 and 16 on the printed circuit board 12 may generate energy in the form of heat, and thus the surface A of the electronic component 15 and the surface B of the electronic component 16 are warmed up. If the power adapter fails to transfer enough heat to the ambient air, the elevated operating temperature may result in damage of the electronic components, a breakdown of the whole power adapter or reduced power conversion efficiency. Therefore, it is important to dissipate the heat generated from the electronic components to increase the power conversion efficiency.

For most power adapters, there are two mechanisms for dissipating heat, i.e. an active heat-dissipating mechanism and a passive heat-dissipating mechanism. The active heat-dissipating mechanism uses an external driving device (e.g. a fan) or a cooling medium (e.g. a coolant or water) to remove heat generated from the power adapter to the ambient air. The passive heat-dissipating mechanism removes the heat generated from the power adapter to the ambient air via natural convention, radiation or conduction. Since the power adapter is developed toward minimization and high power, the electronic components mounted on the printed circuit board of this power adapter may generate more heat. If the power adapter fails to transfer enough heat to the ambient air, the elevated operating temperature may result in damage of the electronic components, a breakdown of the whole power adapter or reduced power conversion efficiency.

Please refer to FIG. 1 again. The power adapter 10 is substantially a rectangular solid, which includes a length L1, a width W1 and a height H. Typically, the, the length L1 to the width W1 (i.e. the aspect ratio) is approximately 2.0. As known, when several rectangular solids having the same volume but different aspect ratio values are considered, such an aspect ratio corresponds to a smaller total surface area of the insulating housing. Due to the small surface area, the heat-dissipating efficiency of the heat-dissipating mechanism is unsatisfied for removing the heat generated from the power adapter to the ambient air via natural convention, radiation or conduction. For increasing the heat transfer area, multiple fins (not shown) may be attached on the surface of the insulating housing 11. The fins may increase complexity and cost of the power adapter. Moreover, the improvement in heat-dissipating efficiency by fins is not satisfied.

Therefore, it is required to provide a heat-dissipating mechanism for increasing heat-dissipating efficiency and power conversion efficiency by selecting an appropriate aspect ratio of the insulting housing.

### SUMMARY OF THE INVENTION

It is an object of the present invention to provide a power supply apparatus having a passive heat-dissipating mechanism for increasing heat-dissipating efficiency and power conversion efficiency by adjusting an aspect ratio of the length to the width.

In accordance with a first aspect of the present invention, there is provided a power supply apparatus having a passive heat-dissipating mechanism. The power supply apparatus includes an insulating housing, a printed circuit board and at least an electronic component. The insulating housing has a closed receptacle therein and includes a first edge, a second edge and a third edge. The first edge is greater than the second edge and the second edge is greater than or equal to the third edge. An aspect ratio of the first edge to the second edge is greater than 2.5. The electronic component is mounted on the printed circuit board.

In accordance with a second aspect of the present invention, there is provided a process for fabricating a power supply apparatus having a passive heat-dissipating mechanism. The process comprises steps of providing an insulating housing having a closed receptacle therein and including a first edge, a second edge and a third edge, wherein the first edge is greater than the second edge and the second edge is greater than or equal to the third edge, and an aspect ratio of the first edge to the second edge is greater than 2.5; providing a printed circuit board having at least an electronic component mounted thereon; and accommodating the printed circuit board within the receptacle of the insulating housing, thereby fabricating the power supply apparatus.

In accordance with a third aspect of the present invention, there is provided a process for fabricating a power supply apparatus having a passive heat-dissipating mechanism. The process comprises steps of providing an insulating housing having a closed receptacle therein and including a first edge, a second edge and a third edge, wherein the first edge is greater than the second edge, the second edge is greater than or equal to the third edge, and the insulating housing has a constant volume; selecting a desired value of the third edge, and adjusting an aspect ratio of the first edge to the second edge to be greater than 2.5; providing a printed circuit board having at least an electronic component mounted thereon; and accommodating the printed circuit board within the receptacle of the insulating housing, thereby fabricating the power supply apparatus.

The above contents of the present invention will become more readily apparent to those ordinarily skilled in the art after reviewing the following detailed description and accompanying drawings, in which:

### BRIEF DESCRIPTION OF THE DRAWINGS

FIG. 1 is a schematic perspective view of a conventional power adapter;

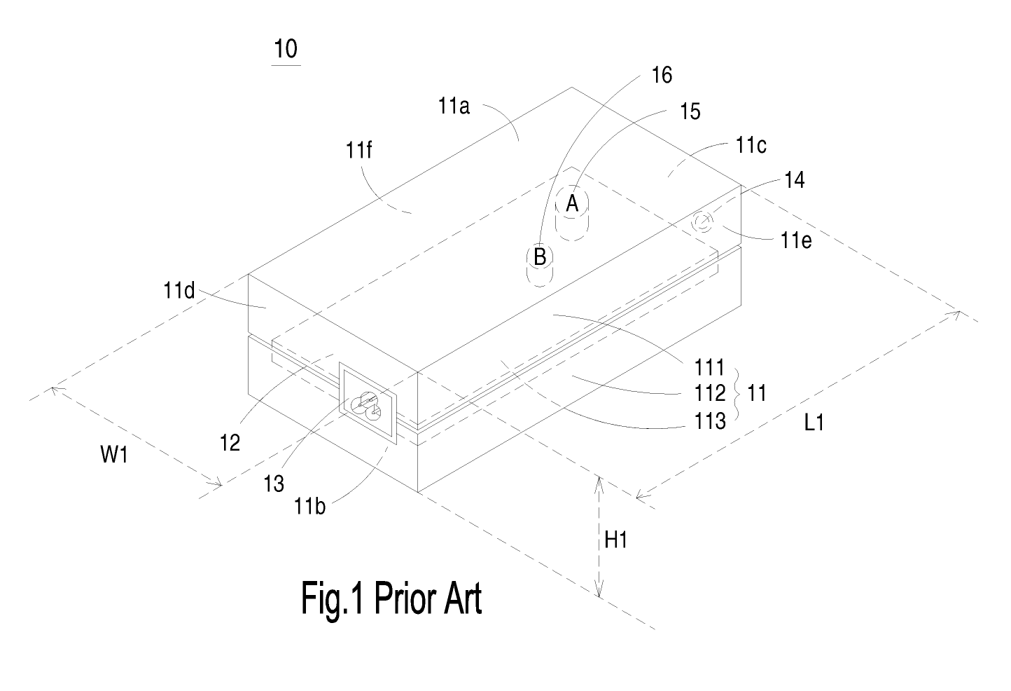

FIG. 2 is a schematic view of a power supply apparatus having a passive heat-dissipating mechanism according to a preferred embodiment of the present invention;

FIG. 3 is a flowchart illustrating a process of fabricating a power adapter having a passive heat-dissipating mechanism according to the present invention; and

FIG. 4 is a flowchart illustrating another process of fabricating a power adapter having a passive heat-dissipating mechanism according to the present invention.

### DETAILED DESCRIPTION OF THE PREFERRED EMBODIMENT

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

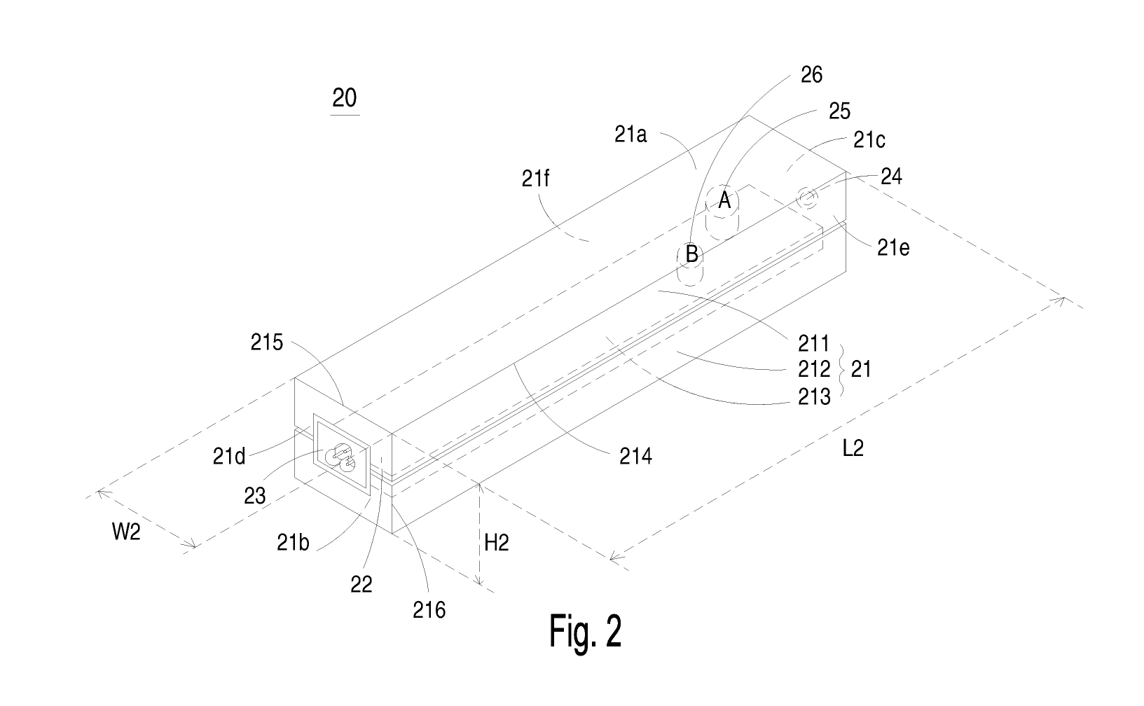

Referring to FIG. 2, a schematic view of a power supply apparatus having a passive heat-dissipating mechanism according to a preferred embodiment of the present invention is illustrated. In this embodiment, an exemplary power supply apparatus is a power adapter 20. The power adapter 20 comprises an insulating housing 21, a printed circuit board 22, a power input member 23 and a power output member 24. The insulating housing 21 is composed of an upper cover 211 and a lower cover 212. A receptacle 213 is defined between the upper cover 211 and the lower cover 212 for accommodating the printed circuit board 22. In this embedment, the insulating housing 21 is substantially a rectangular housing or a stick-shaped housing, and includes a first surface 21a, a second surface 21b, a third surface 21c, a fourth surface 21d, a fifth surface 21e and a sixth surface 21f. The insulating housing 21 includes a first edge 214, a second edge 215 and a third edge 216 corresponding to a length L2, a width W2 and a height H2, respectively. In this embodiment, L2>W2≧H2. The L2/W2 aspect ratio of the insulating housing 21 is greater than 2.5, and preferably in a range of from 2.5 to 20.0. In comparison with the conventional power adapter having the same volume but having an aspect of 2.0, the overall heat transfer area of the insulating housing 21 of the present power adapter 20 is considerably increased. As a consequence, the passive heat-dissipating mechanism of the power adapter 20 may increase the heat-dissipating efficiency and power conversion efficiency by removing the heat generated from the power adapter to the ambient air via natural convention, radiation or conduction.

There are several electronic components mounted on the printed circuit board 22 to provide power conversion. For clarification, only two electronic components 25 and 26 are shown in this drawing. The power input member 23 and the power output member 24 are disposed on opposite sides of the insulating housing 21, and are electrically connected to the printed circuit board 22 (not shown). Via the power input member 23 and the power output member 24, the external power source and the electronic product are respectively connected to the power adapter 20. An AC voltage transmitted from the external power source is converted by the circuitry of a printed circuit board 22 inside the power adapter 20 into a regulated DC output voltage for powering the electronic product. During power conversion, the electronic components 25 and 26 on the printed circuit board 22 may generate energy in the form of heat, and thus the surface A of the electronic component 25 and the surface B of the electronic component 26 are warmed up. The heat generated from the electronic components 25 and 26 is transferred to the ambient air through the receptacle 213 and the insulating housing 21 via natural convention, radiation or conduction. As a consequence, the passive heat-dissipating mechanism of the power adapter 20 is effective to remove the heat generated from the power adapter 20 to the ambient air via natural convention, radiation or conduction. Generally, the heat transfer rate of radiation or conduction is in proportional to the overall surface area. Since the overall surface area of the insulating housing 21 having the L2/W2 aspect ratio in a range of from 2.5 to 20.0 is increased in comparison with the conventional power adapter, the passive heat-dissipating mechanism of the power adapter 20 may increase the heat-dissipating efficiency and power conversion efficiency.

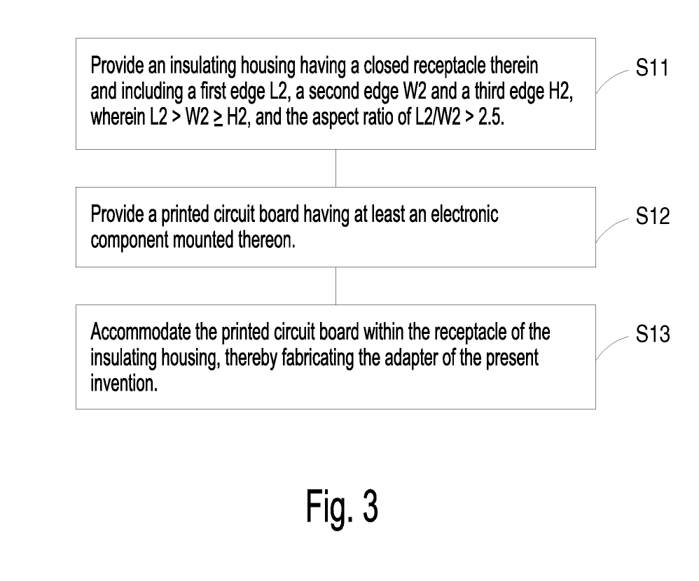

Hereinafter, a process of fabricating a power adapter having a passive heat-dissipating mechanism will be illustrated with reference to a flowchart of FIG. 3 and also FIG. 2. First of all, in the step S11, an insulating housing 21 having a closed receptacle 213 is provided. The insulating housing 21 includes a first edge 214, a second edge 215 and a third edge 216 corresponding to a length L2, a width W2 and a height H2, respectively. In this embodiment, L2>W2≧H2. The L2/W2 aspect ratio of the insulating housing 21 is greater than 2.5, and preferably in a range of from 2.5 to 20.0. Then, in the step S12, the printed circuit board 22 having the electronic components 25 and 26 mounted thereon is provided. Afterwards, in the step S13, the printed circuit board 22 is accommodated within the receptacle 213 of the insulating housing 21, thereby fabricating the power adapter 20 of the present invention. Optionally, after the step S12, the process may further include a step of electrically connecting a power input member 23 and a power output member 24 to the printed circuit board 22.

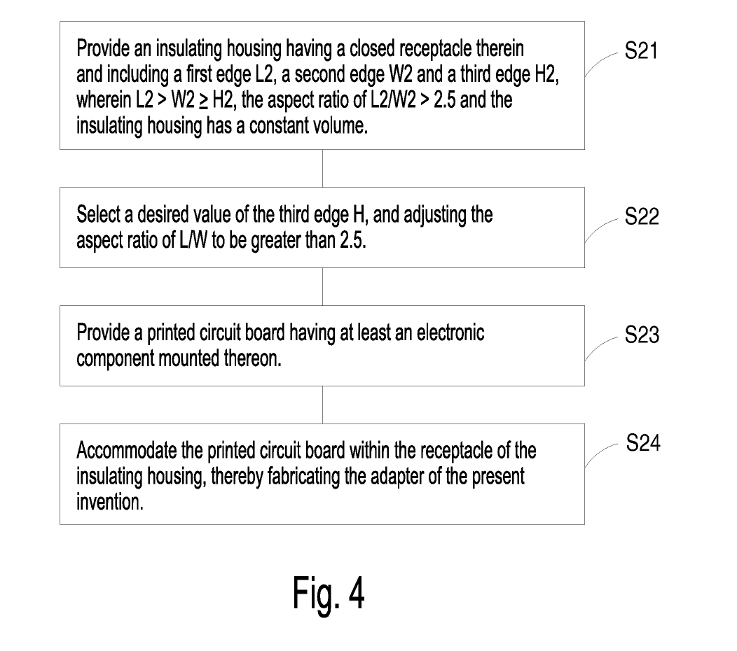

A further process of fabricating a power adapter having a passive heat-dissipating mechanism is illustrated in FIG. 4 and also FIG. 2. First of all, in the step S21, an insulating housing 21 having a closed receptacle 213 is provided. The insulating housing 21 includes a first edge 214, a second edge 215 and a third edge 216 corresponding to a length L2, a width W2 and a height H2, respectively. In this embodiment, L2 is greater than W2 and W2 is greater than or equal to H2. The insulating housing 21 has a constant volume. Then, in the step S22, a desired value of the height H2 is selected, and the L2/W2 aspect ratio of the insulating housing 21 is adjusted to be greater than 2.5, and preferably in a range of from 2.5 to 20.0. Then, in the step S23, the printed circuit board 22 having the electronic components 25 and 26 mounted thereon is provided. Afterwards, in the step S24, the printed circuit board 22 is accommodated within the receptacle 213 of the insulating housing 21, thereby fabricating the power adapter 20 of the present invention. Optionally, after the step S22, the process may further include a step of electrically connecting a power input member 23 and a power output member 24 to the printed circuit board 22.

From the above description, the overall heat transfer area of the insulating housing of the present power adapter is considerably increased in comparison with the conventional power adapter having the same volume but having an aspect of 2.0. Accordingly, the power supply apparatus of the present invention is capable of enhancing the heat-dissipating efficiency and the power conversion efficiency of the power adapter by adjusting an aspect ratio of the first edge to the second edge.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A power supply apparatus having a passive heat-dissipating mechanism, said power supply apparatus comprising:
an insulating housing having a closed receptacle therein and including a first edge, a second edge and a third edge, wherein said first edge is greater than said second edge and said second edge is greater than or equal to said third edge, and an aspect ratio of said first edge to said second edge is greater than 2.5;
a printed circuit board accommodated in said receptacle of said insulating housing; and
at least an electronic component mounted on said printed circuit board.

2. The power supply apparatus according to claim 1 wherein said aspect ratio of said first edge to said second edge is in a range of from 2.5 to 20.0.

3. The power supply apparatus according to claim 1 wherein said power supply apparatus is a power adapter.

4. The power supply apparatus according to claim 1 further comprising a power input member and a power output member disposed on opposite sides of said insulating housing and electrically connected to said printed circuit board.

5. The power supply apparatus according to claim 1 wherein said insulating housing is substantially a rectangular solid, and said first edge, said second edge and said third edge correspond to a length, a width and a height, respectively.

6. The power supply apparatus according to claim 5 wherein said insulating housing is substantially stick-shaped.

7. A process for fabricating a power supply apparatus having a passive heat-dissipating mechanism, said process comprising steps of:
providing an insulating housing having a closed receptacle therein and including a first edge, a second edge and a third edge, wherein said first edge is greater than said second edge and said second edge is greater than or equal to said third edge, and an aspect ratio of said first edge to said second edge is greater than 2.5;
providing a printed circuit board having at least an electronic component mounted thereon; and
accommodating said printed circuit board within said receptacle of said insulating housing, thereby fabricating said power supply apparatus.

8. The process according to claim 7 wherein said aspect ratio of said first edge to said second edge is in a range of from 2.5 to 20.0.

9. The process according to claim 7 wherein said power supply apparatus is a power adapter.

10. The process according to claim 7 further comprising a step of electrically connecting a power input member and a power output member to said printed circuit board.

11. The process according to claim 7 wherein said insulating housing is substantially a rectangular solid, and said first edge, said second edge and said third edge correspond to a length, a width and a height, respectively.

12. The process according to claim 11 wherein said insulating housing is substantially stick-shaped.

13. A process for fabricating a power supply apparatus having a passive heat-dissipating mechanism, said process comprising steps of:
providing an insulating housing having a closed receptacle therein and including a first edge, a second edge and a third edge, wherein said first edge is greater than said second edge, said second edge is greater than or equal to said third edge, and said insulating housing has a constant volume;
selecting a desired value of said third edge, and adjusting an aspect ratio of said first edge to said second edge to be greater than 2.5;
providing a printed circuit board having at least an electronic component mounted thereon; and
accommodating said printed circuit board within said receptacle of said insulating housing, thereby fabricating said power supply apparatus.

14. The process according to claim 13 wherein said aspect ratio of said first edge to said second edge is in a range of from 2.5 to 20.0.

15. The process according to claim 13 wherein said power supply apparatus is a power adapter.

16. The process according to claim 13 further comprising a step of electrically connecting a power input member and a power output member to said printed circuit board.

17. The process according to claim 13 wherein said insulating housing is substantially a rectangular solid, and said first edge, said second edge and said third edge correspond to a length, a width and a height, respectively.

18. The process according to claim 17 wherein said insulating housing is substantially stick-shaped.
